(19) United States
(12) Patent Application Publication
(10) Pub. No.: US 2026/0262172 A1
(43) Pub. Date: Sep. 3, 2026

(54) LIGHTWEIGHT FLEXIBLE TOUCH DISPLAY WITH SEPARATE RIGID MOUNTING COMPONENT

(71) Applicant: Flatfrog Laboratories AB, Lund (SE)

(72) Inventors: Aleksander Kocovski, Malmö (SE); Patrik Svensson, Hjärup (SE); Ola Wassvik, Lammhult (SE); Daniel Gredinger, Löddeköpinge (SE); Mattias Krus, Lund (SE)

(21) Appl. No.: 19/489,224

(22) PCT Filed: Jun. 7, 2024
(86) PCT No.: PCT/SE2024/050554

§ 371 Date: Dec. 1, 2025

(30) Foreign Application Priority Data
Jun. 9, 2023 (SE) 2330275-5
Jun. 9, 2023 (SE) 2330276-3

(51) Int. Cl. H05K 5/02; H05K 5/00

(52) U.S. Cl. CPC H05K 5/02; H05K 5/0018

(57) ABSTRACT

The invention relates to a touch display system comprising a main unit with a display and a touch sensor, and a mounting component. The main unit is flexible when not connected to the mounting component, and the mounting component is configured to provide rigidity to the main unit when connected to the main unit. This touch display system allows for the use of lightweight layer components in the main unit, reducing the overall weight and cost of the touch screen.

### FIELD

The present technology relates to the field of touch screen displays, particularly to large touch screen displays used in various applications such as interactive digital signage, information kiosks, and collaborative workspaces. The technology focuses on the design, materials, and construction of touch screen displays to improve their overall performance, weight, and cost efficiency.

### BACKGROUND

Touch screen technology has become increasingly popular in recent years, with applications ranging from smartphones and tablets to large interactive displays used in various industries, such as retail, education, and entertainment. Large touch screens, typically greater than 43 inches diagonally across, are particularly useful for providing an immersive and interactive experience for users. However, the production and implementation of these large touch screens present several challenges, primarily due to the heavy and expensive materials required for their construction.

In conventional large touch screen designs, a rigid structure is necessary to control the shape of the touch glass and maintain the integrity of the display. This rigid structure typically consists of various components, such as aluminum and steel elements, including a rear cover, edge profiles, and glass carrier components. Additionally, the cover glass itself must be thick and heavy to provide the necessary rigidity, further contributing to the overall weight and cost of the touch screen.

The use of heavy and expensive materials in the construction of large touch screens not only increases production costs but also reduces affordability for consumers and businesses. Furthermore, the added weight of these materials can make installation and transportation of the touch screens more difficult and cumbersome.

Previous displays such as TVs or monitors are available without VESA mounts, which offer alternative attachment structures on the edge of the rear cover of the display system. However, these alternative mounting arrangements do not provide the necessary rigidity typically required for touch screens, and would result in potential issues with the touch detection performance in such application.

In summary, the prior art in large touch screen technology is limited by the reliance on heavy and expensive materials to provide the necessary rigidity and structural integrity. This not only increases production costs and reduces affordability but also presents challenges in terms of installation and transportation. There is a need for an improved large touch screen design that addresses these issues while maintaining the performance and functionality of the display.

### SUMMARY

In a first aspect, the touch display system comprises a main unit and a mounting component. The main unit comprises a display and a touch sensor. The main unit is flexible when not connected to the mounting component, and the mounting component is configured to provide rigidity to the main unit when connected to the main unit.

In some embodiments, a front surface of the display may assume a pre-defined curvature when the mounting component is connected to the main unit. The front surface may assume the pre-defined curvature when the mounting component is connected to the main unit and a rigid structure such as a wall or floor stand. The main unit may further comprise a transparent display cover, which may be a front surface of the display, and a back cover. Additionally, the main unit may comprise an edge cover attached to the edges of the main unit. The edge cover may be flexible to conform to a curvature of the front surface. The edge cover may be configured to distribute light from the touch sensor across the front surface. The edge cover may also be connected to the back cover.

In some embodiments, the main unit may comprise support points positioned on a rear surface of the main unit for connecting the main unit to the mounting component. The mounting component may comprise a first interface for removably connecting to the support points of the main unit, a body, and a second interface for connecting to a rigid structure. The first interface may have a curved shape. The second interface of the mounting component may be adjustable to adjust a distance between the main unit and the rigid structure when connected to the rigid structure. The first interface and/or the second interface may be adjustable to adjust a curvature of a front surface of the display. The second interface may comprise adjustable mounting points being individually adjustable to configure a uniformly shaped surface of the mounting component, and/or a symmetrically shaped surface of the mounting component, opposite a non-uniformly shaped wall, to which the main unit is connectable. A first set of adjustable mounting points may be arranged adjacent a center region of the mounting component and are configured to pull the mounting component towards a rigid surface such as a wall, and second set of adjustable mounting points may be arranged outside the first set of adjustable mounting points, closer to a perimeter of the mounting component than the first set of adjustable mounting points, and may be configured to push the mounting component from the rigid surface.

In some embodiments, the display has a thickness of less than 5 mm. The touch display system may have a first user configuration, when the main unit is disconnected from the mounting component, in which the main unit is flexing and the front surface of the display has a variable curvature, and a second user configuration, when the main unit is connected to the mounting component, in which the front surface of the display has a pre-defined curvature and the touch sensor is configured to detect touch input on the display.

According to a second aspect a method for partitioning a touch display into a main unit and a mounting component is provided comprising providing a lightweight stack of layer components for the main unit comprising a display, a transparent display cover, and a back cover; bonding, taping, or screwing together the layer components into a sandwich structure; and connecting a first interface of the mounting component to support points of the main unit. The mounting component provides rigidity to the main unit and a pre-defined curvature to the front surface of the display when connected to the main unit. The method may further comprise adjusting a distance between the main unit and a rigid structure such as a wall or a floor stand using an adjustable second interface of the mounting component when connected to the rigid structure.

### BRIEF DESCRIPTION OF THE DRAWINGS

The disclosure will now be described in more detail with reference to the accompanying drawings, in which:

FIG. 1 is a front view of the main unit of the touch display according to an embodiment of the invention;

FIG. 2 is a cross-sectional view of the main unit, illustrating the layer components and edge covers;

FIG. 3 is a rear view of the main unit, showing the support points for connecting to the mounting component;

FIG. 4 is a perspective view of the mounting component, illustrating the first interface for connecting to the support points of the main unit and the second interface for connecting to a rigid structure;

FIG. 5 is a perspective view of the mounting component, illustrating the first interface being connected to the support points of the main unit and the second interface for connecting to a rigid structure;

FIG. 6 is a perspective view of the mounting component, according to an example of the disclosure;

FIG. 7 is a side view of the mounting component attached to a flat wall, according to an example of the disclosure;

FIG. 8a is a side view of the mounting component attached to a concave wall before adjustment of the mounting component, according to an example of the disclosure;

FIG. 8b is a side view of the mounting component attached to a concave wall after adjustment of the mounting component, according to an example of the disclosure;

FIG. 9a is a side view of the mounting component attached to a convex wall before adjustment of the mounting component, according to an example of the disclosure;

FIG. 9b is a side view of the mounting component attached to a convex wall after adjustment of the mounting component, according to an example of the disclosure;

FIG. 10a is a perspective view of the mounting component connected to the main unit, according to an example of the disclosure;

FIG. 10b is a view of the mounting component, according to an example of the disclosure;

FIG. 11a is a perspective view of the mounting component connected to the main unit, according to an example of the disclosure;

FIG. 11b is a view of the mounting component, according to an example of the disclosure;

FIGS. 12a-b are perspective detail views of the mounting component, according to an example of the disclosure; and

FIGS. 13a-b are views of the mounting component, according to examples of the disclosure.

### DETAILED DESCRIPTION

The present disclosure will now be described in detail with reference to example embodiments. It should be understood that these example embodiments are provided for illustrative purposes only and are not intended to limit the scope of the present disclosure.

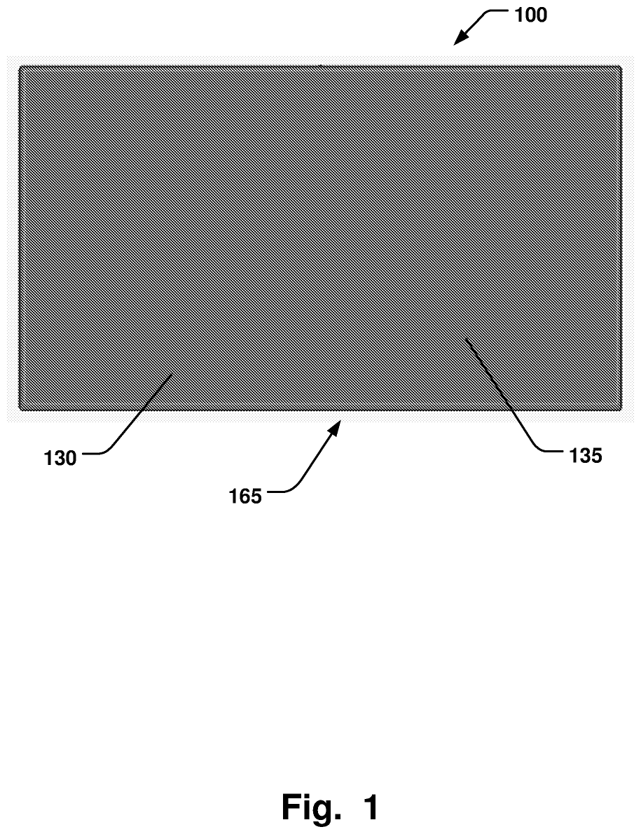

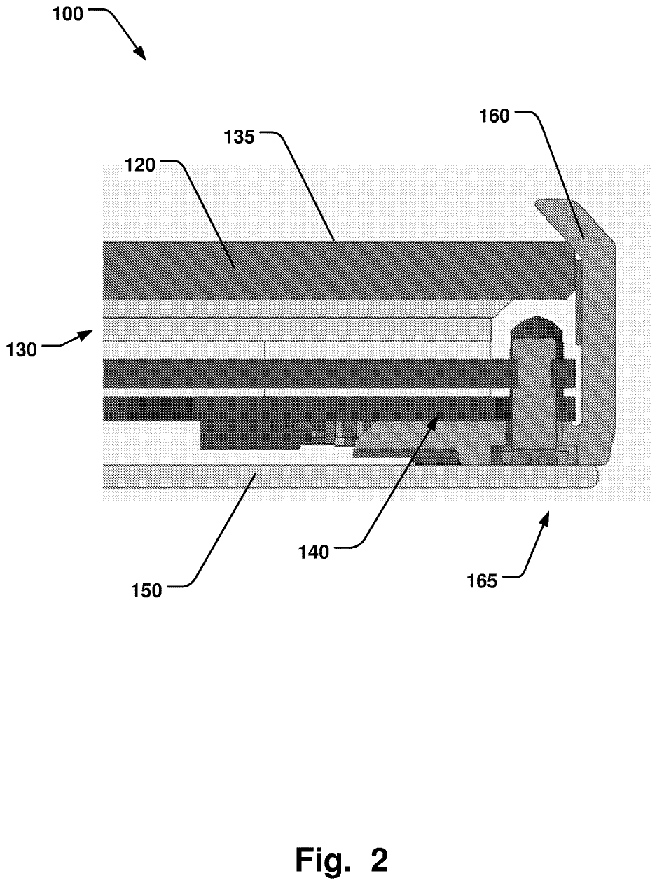

According to an embodiment shown in FIG. 1, the touch display system 10 comprises a main unit 100 having a display 130. The display 130 may be an OLED, LCD, AMOLED, ink display, LED, quantum dot, micro LED, or transflective display. The touch display system 10 comprises a touch sensor 140 to provide touch functionality on a front surface 135 of the display 130, as seen in FIG. 2. The main unit 100 may also comprise a transparent display cover 120 arranged as a front surface 135 of the display 130. The transparent display cover 120 may be made of materials such as tempered glass, polycarbonate, PET, PMMA, aluminosilicate glass, PSP, TPU, PVC, PLA, or polyolefin film.

Referring to FIG. 2, the main unit 100 comprises layer components 110 such as the display 130, touch sensor 140, and optional transparent display cover 120. The touch sensor 140 may be an optical touch sensor or a projected capacitive touch sensor. The main unit 100 may also comprise a back cover 150 that provides protection for the touch sensor 140 and display 130. The back cover 150 may be made of materials such as aluminum, carbon fiber, stainless steel, or plastic. The main unit 100 may further comprise edge covers 160 attached to the edges 165 of the main unit 100 to provide protection and a finished appearance. The edge covers 160 may be flexible to conform to a curvature of the front surface 135 of the display 130.

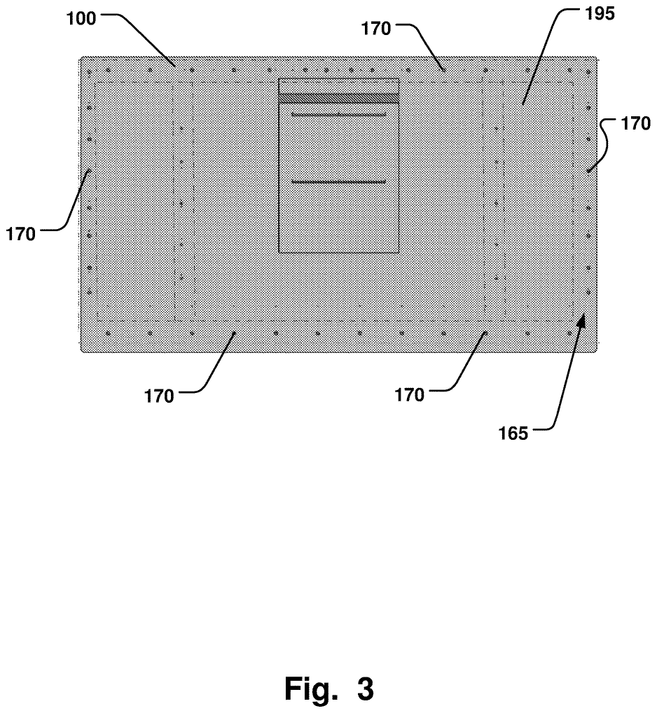

In the embodiment shown in FIG. 3, the main unit 100 comprises support points 170 positioned on a rear surface 195 of the main unit 100 for connecting the main unit 100 to a mounting component 200. The support points 170 may be positioned along the edges 165 of the main unit 100 or in the center of the rear surface of the main unit 100. The support points 170 may be magnets, magnet strips, adhesive pads, clamps, clips, hooks, rivets, screws, snap-in connectors, suction cups, or Velcro strips.

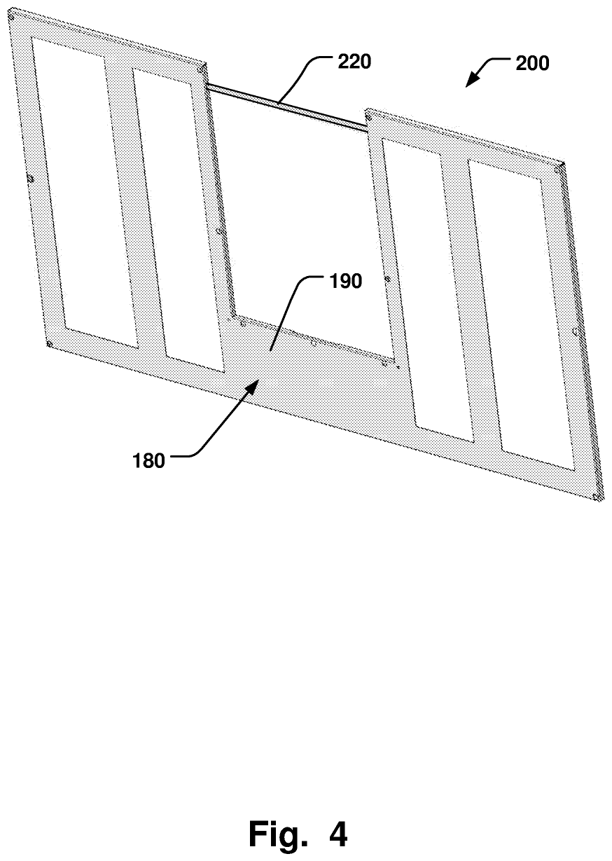

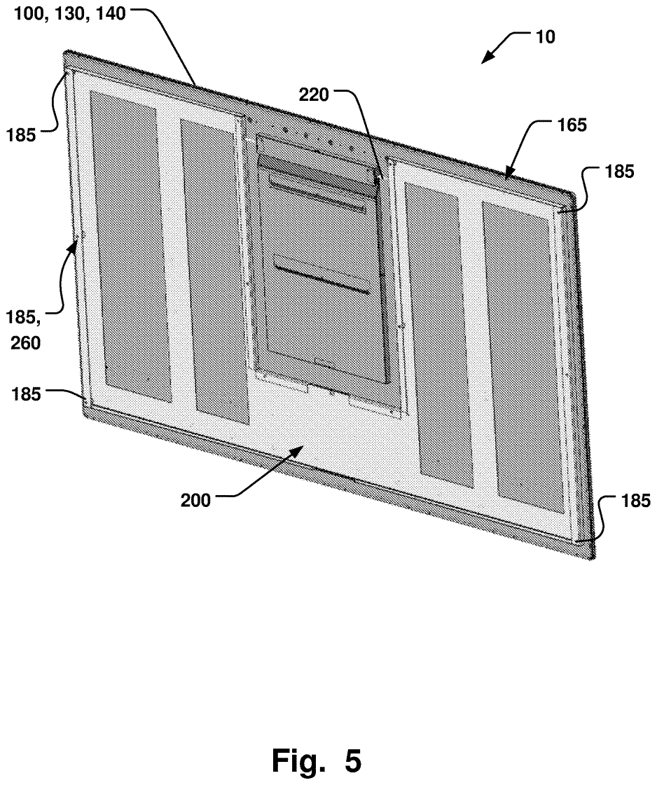

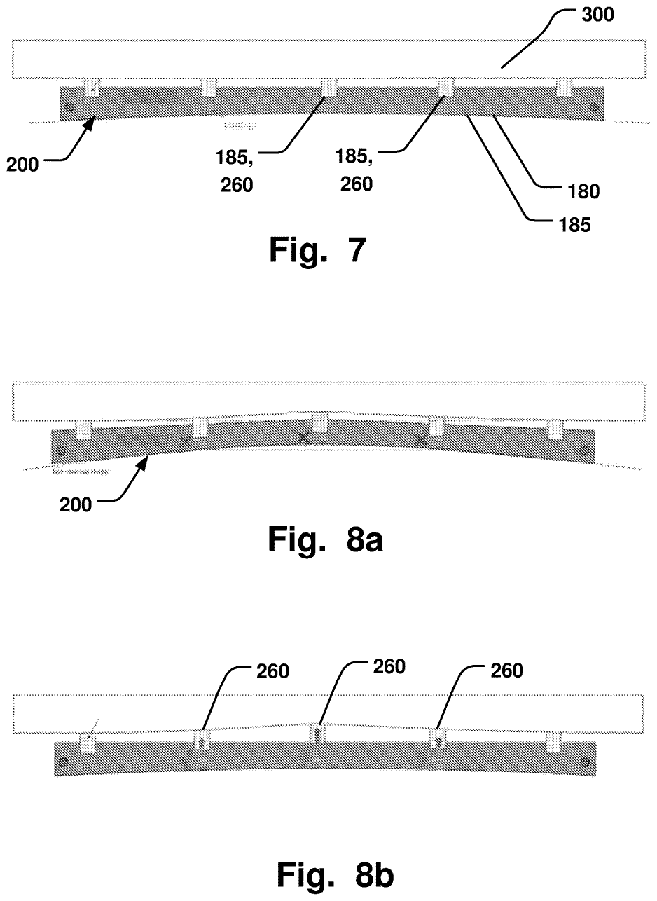

FIG. 4 illustrates an embodiment of the mounting component 200, which comprises a first interface 180 for removably connecting to the support points 170 of the main unit 100 and a body 190. A second interface 185 for connecting the mounting component 200 to a rigid structure such as a wall 300 or floor stand is shown in FIG. 5. The first interface 180 and/or the second interface 185 may be adjustable to adjust a curvature of the front surface 135 of the display 130. The second interface 185 may also be adjustable to adjust the distance between the main unit 100 and the rigid structure when connected to the rigid structure, as described further below with reference to FIGS. 7-9.

FIG. 5 shows an example of the touch display system 10 comprising the main unit 100 connected to the mounting component 200. The second interface 185 of the mounting component 200 may be connected to a rigid structure 300 such as a wall or floor stand. The mounting component 200 provides rigidity to the main unit 100 when connected and may optionally provide a controlled shape for the main unit 100 when connected. The mounting component 200 may be configured to provide rigidity and a controlled shape to the main unit 100 even in case the mounting component 200 is attached to a surface or component which is less rigid than a wall, such as a semiflexible stand or VESA mount thereof.

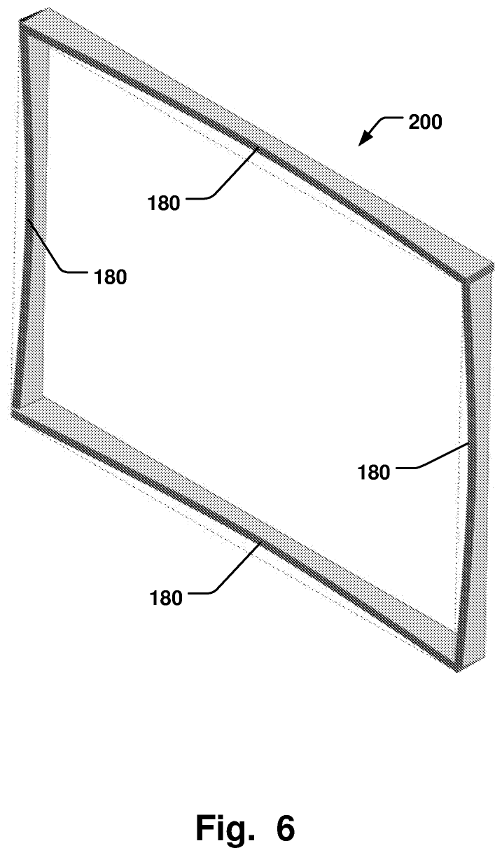

FIG. 6 shows an example where the first interface 180 of the mounting component 200 has a curved shape. The main unit 100 may thus assume a controlled curved shape when attached to the first interface 180.

The second interface 185 may comprise adjustable mounting points 260 being individually adjustable to configure a uniformly shaped surface of the mounting component 200, and/or a symmetrically shaped surface of the mounting component 200, opposite a non-uniformly shaped wall, to which the main unit 100 is connectable. The adjustable mounting points 260 can comprise adjustable spacers, such as telescoping spacers, screw-in spacers, interlocking spacers, or spring-loaded spacers.

FIG. 7 shows a side view of the mounting component 200 attached to a flat wall 300. Adjustable mounting points 260 of the second interface 185 are attached to the wall 300. The first interface 180 of the mounting component 200 has a concave shape. Thus, when the first interface 180 is connected to the support points 170 of the main unit 100 (not shown), it provides a controlled shape, such as a concave shape to a front surface 135 of the display 130 of the main unit 100. A defined concave shape of the front surface 135 provides for increased touch detection performance of the touch display system 10.

In the embodiment shown in FIGS. 8a and 8b, the mounting component 200 is attached to a concave wall. FIG. 8a shows the mounting component 200 before adjustment of the mounting points 260 of the second interface 185. FIG. 8b shows the mounting component 200 after adjustment of the mounting points 260 to compensate for the concave wall shape which otherwise induce too much concavity to a front surface 135 of the main unit 100 when connected to the mounting component 200.

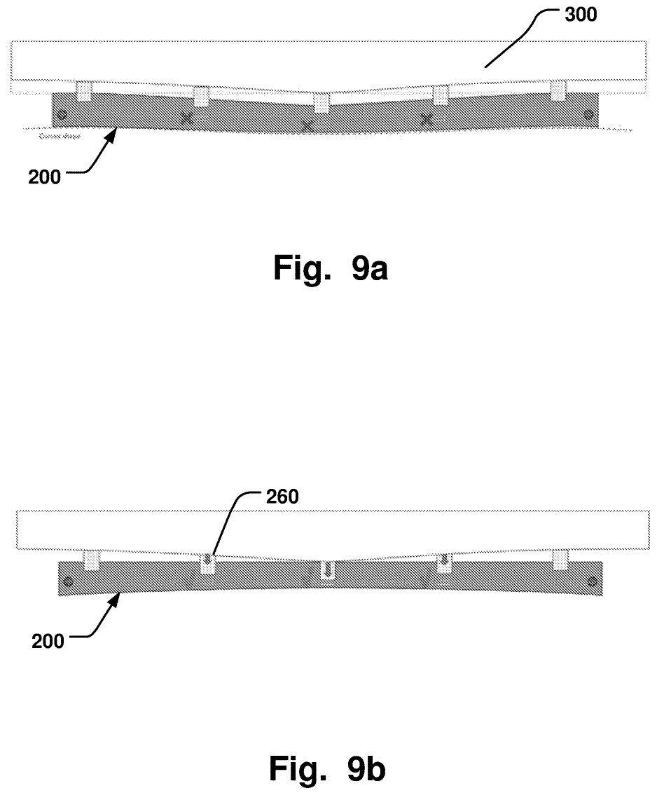

Similarly, in the embodiment shown in FIGS. 9a and 9b, the mounting component 200 is attached to a convex wall. FIG. 9a shows the mounting component 200 before adjustment of the mounting component 200. FIG. 9b shows the mounting component 200 after adjustment of the mounting component 200 to compensate for the convex wall shape so that instead a concave front surface 135 of the main unit 100 can be provided when connected to the mounting component 200. The adjustable mounting points 260 allow compensation of a wall shape selected from the group consisting of convex, concave, and S-shaped wall shapes.

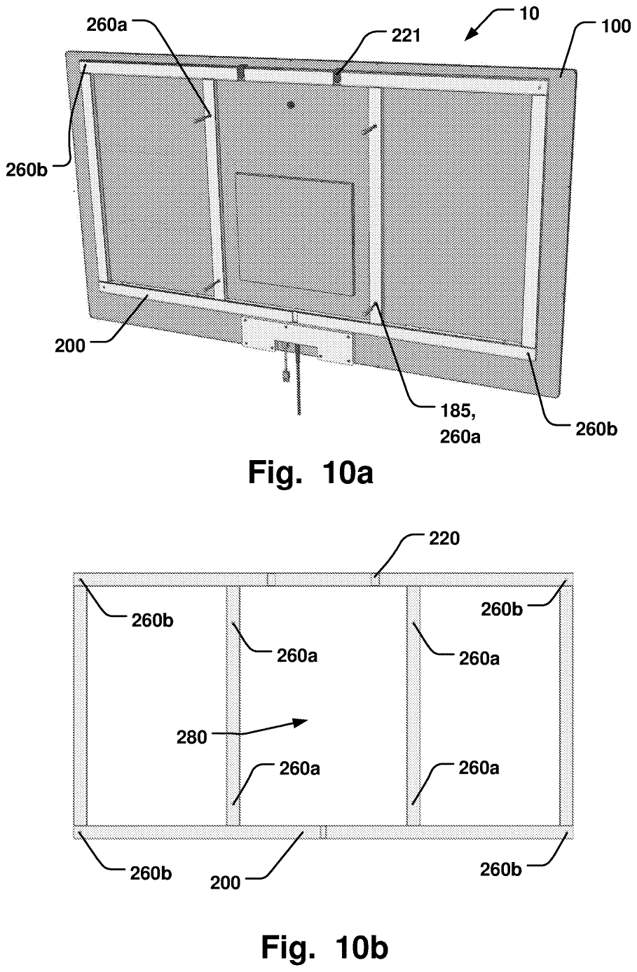

FIG. 10a show a further example of the touch display system 10 where the main unit 100 is connected to the mounting component 200. The mounting component 200 thus provides rigidity and a defined shape to the main unit 100, which may otherwise be flexible. The second interface 185 is adjustable as described above to set a shape of the mounting component 200, such as a concave shape, in order to induce a corresponding concave shape to the main unit 100 when connected to the mounting component 200. FIG. 10b shows an example of the mounting component 200 when not connected to the main unit 100.

A first set of adjustable mounting points 260a may be arranged adjacent a center region 280 of the mounting component 200 and are configured to pull the mounting component 200 towards a rigid surface 300 such as a wall. A second set of adjustable mounting points 260b may be arranged outside the first set of adjustable mounting points 260a, closer to a perimeter of the mounting component 200 than the first set of adjustable mounting points 260a. The second set of adjustable mounting points 260b are configured to push the mounting component 200 from the rigid surface. FIGS. 10a-b show an example of such first and second sets of adjustable mounting points 260a, 260b. The center region 280 of the mounting component 200 may thus be pulled towards the wall, whereas the perimeter of the mounting component 200 may be pushed from the wall, in order to provide the desired curvature of the mounting component 200 and thus the corresponding induced curvature of a flexible main unit 100 when connected to the mounting component 200. The rigidity provided by the mounting component 200 also reduces vibrations to be transferred to the main unit 100.

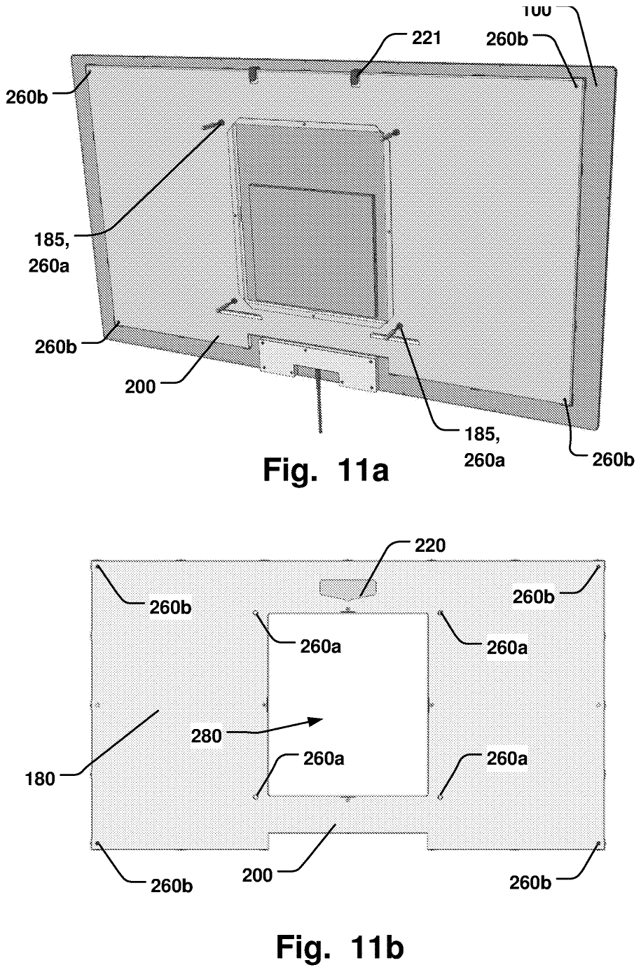

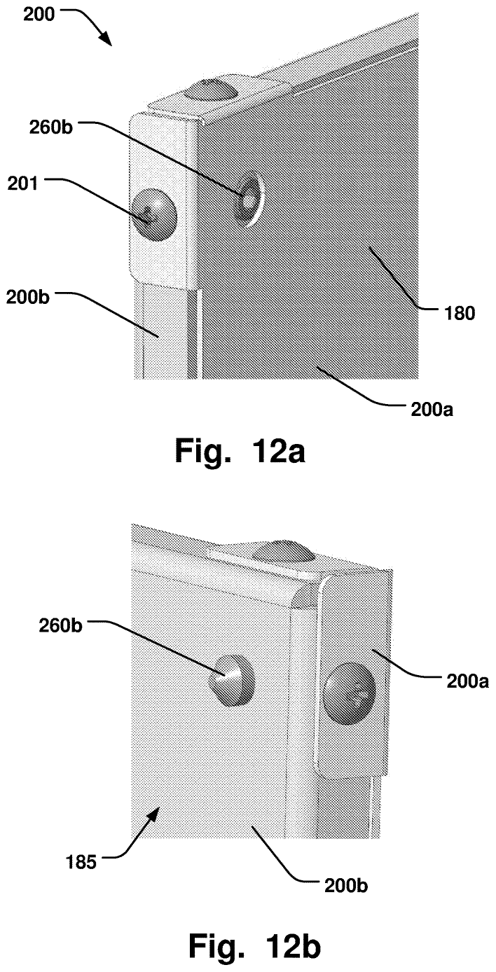

FIGS. 11a-b show a further example of the touch display system 10 where the main unit 100 is connected to the mounting component 200 (FIG. 11a) and of the mounting component 200 when disconnected from the main unit 100 (FIG. 11b). First and second sets of adjustable mounting points 260a, 260b, are illustrated and provide for setting a defined shape of the mounting component 200 in a corresponding manner as described in relation to FIGS. 10a-b. Whereas FIGS. 10a-b show an example of a mounting component 200 comprising a plurality of connected bars, arms and/or struts to form a frame-like component, the mounting component 200 in FIGS. 11a-b is an integrated unit having an increased surface area, thus covering a larger area of the main unit 100 when connected thereto. The mounting component 200 in FIGS. 11a-b may comprise one or more sheets or layers of material, such as a metal and/or polymer material. FIGS. 12a-b show an example where the mounting component 200 comprises first and second components 200a, 200b, connectable to each other, where each of the first and second components 200a, 200b, may comprise a sheet or layer of material. The first component 200a may be connected to the second component 200b with a fastener 201, such as a screw, rivet, bolt, clamp, as exemplified in FIG. 12a. The first and second components 200a, 200b, may form a semi-hollow unit. The first component 200a may be facing the main unit 100 and thus comprising the first interface 180 of the mounting component 200. The second component 200b may thus comprise the second interface 185 of the mounting component 200, and may be configured to be arranged against a wall or another mounting surface. In some examples a separation between the first and second components 200a, 200b, may vary across the area covering the main unit. E.g. the separation may be less adjacent a center region 280 compared to the separation closer to the perimeter of the mounting component 200 so that a concave shape is attained. The first and second components 200a, 200b, may be mounted together to provide such concave shape, e.g. by screws or bolts.

FIGS. 12a-b show an example of a second set of adjustable mounting points 260b configured to push the mounting component 200 from a rigid surface 300. The adjustable mounting points 260b may comprise screws that project from the second component 200b with an adjustable length in order to push the mounting component 200 from the rigid surface 300 and adjust a distance between the mounting component 200 and the rigid surface 300 to provide the desired curvature of the mounting component 200. The adjustable mounting points 260b may in addition reduce the amount of vibrations transferred from the mounting surface to the mounting component 200 and the main unit 100 since a separation is created between the main body of the mounting component 200 and the mounting surface. A first set of adjustable mounting points 260a may be arranged adjacent a center region 280 of the mounting component 200 as illustrated in FIGS. 11a-b.

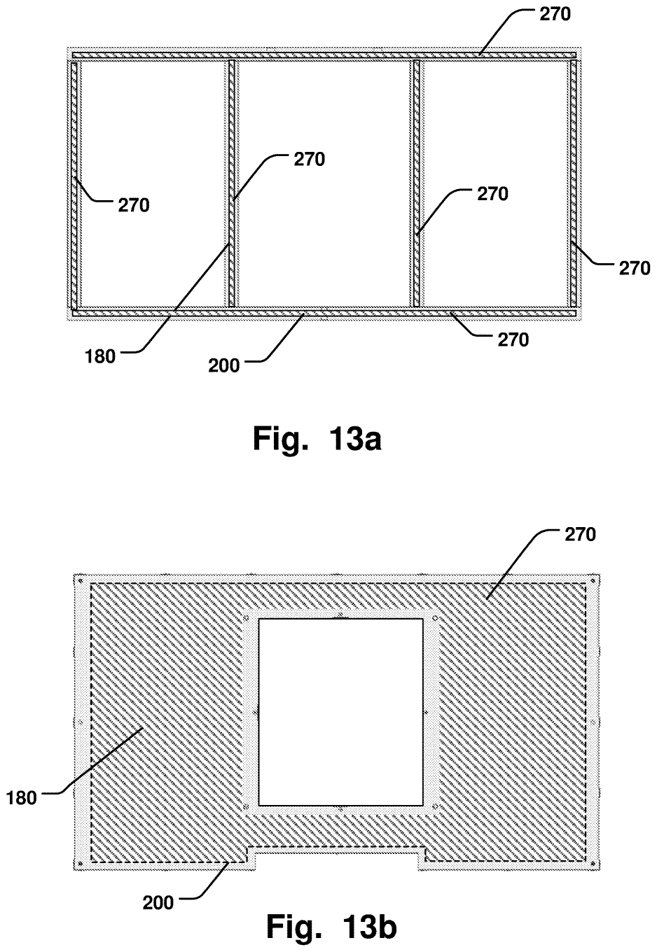

The touch display system 10 may comprise a retention element 270 for removably connecting the main unit 100 to the mounting component 200. FIGS. 13a-b show examples of retention elements 270 provided on the mounting component 200.

FIG. 13a illustrates a retention element 270 provided on struts, rods, and/or arms of a frame-like mounting component 200, whereas FIG. 13b illustrates a retention element 270 provided over a larger area of a sheet-like mounting component 200. In either case, the retention element 270 is configured anchor the main unit 100 so that it conforms to the curvature of the mounting component 200. FIGS. 13a-b illustrate examples where the retention element 270 is provided on the mounting component 200 for subsequent attachment to the main unit 100. In other examples the retention element 270 is provided on the main unit 100 for subsequent attachment to the mounting component 200. In either case, the curvature of the mounting component 200 is transferred to the main unit 100 when being connected together. The retention element 270 may thus be arranged at the support points 170 of the main unit 100 and/or at the first interface 180 of the mounting component 200. The retention element 270 may comprise one or more magnets. In other examples the retention element 270 comprises an adhesive or Velcro material, or other material configured to removably fix the main unit 100 to the mounting component 200.

The first interface 180 may comprise a first support component 220 configured to support the weight of the main unit 100 when the mounting component 200 is mounted to a rigid surface such as a wall. FIG. 4 illustrates a first support component 220 which comprise a rod-or strut-like structure which is configured to carry the weight of the main unit 100 as illustrated in FIG. 5. FIG. 10a-b or 11a-b show other examples where hooks or other fasteners 221 of the main unit 100 engage with a first support component 220 of the mounting component 200.

The touch display system 10 may have a first user configuration, when the main unit 100 is disconnected from the mounting component 200, in which the main unit 100 is flexing and the front surface 135 of the display 130 has a variable curvature, and a second user configuration, when the main unit 100 is connected to the mounting component 200, in which the front surface 135 of the display 130 has a pre-defined curvature and the touch sensor 140 is configured to detect touch input on the display 130.

The disclosed touch display system 10 and method for partitioning a touch display into a main unit 100 and a mounting component 200 provide advantages such as reduced weight and cost by using lightweight layer components and a separate mounting component for rigidity. This allows for the use of lightweight layer components in the main unit 100, reducing the overall weight and cost of the touch display system 10.

Further examples of the touch display system 10 are described in the following.

### 1. Main Unit Configuration

The main unit 100 configuration of the touch display system 10 comprises various components and materials that contribute to the overall functionality and performance of the system 10. In one example, the main unit 100 comprises layer components 110, such as the display 130, touch sensor 140, and optional transparent display cover 120. The main unit 100 may also comprise a back cover 150 and edge covers 160, which provide protection and a finished appearance to the touch display system 10.

### 1.1. Layer Components and Materials

The layer components 110 of the main unit 100 may be made from various materials, depending on the desired properties and performance of the touch display system 10. These materials contribute to the lightweight and flexible nature of the main unit 100, which is advantageous for reducing the overall weight and cost of the touch screen.

### 1.1.1. Display Types and Thickness

In some examples, the display 130 may be an OLED (Organic Light Emitting Diode) display, LCD (Liquid Crystal Display) display, AMOLED (Active Matrix Organic Light Emitting Diode) display, ink display (Electronic Ink Display), LED (Light Emitting Diode) display, quantum dot display, micro LED display, or transflective display. The display 130 may have a thickness of less than 10 mm, and in some examples, less than 5 mm. The thinness of the display 130 contributes to the lightweight and flexible nature of the main unit 100.

### 1.1.2. Transparent Display Cover Materials

The optional transparent display cover 120 may be made of materials such as tempered glass, polycarbonate, PET (Polyethylene terephthalate), PMMA (Polymethyl methacrylate), aluminosilicate glass, PSP (Polysiloxane), TPU (Thermoplastic polyurethane), PVC (Polyvinyl chloride), PLA (Polylactic acid), or polyolefin film. The transparent display cover 120 may be arranged as a front surface 135 of the display 130, providing protection and enhancing the appearance of the touch display system 10.

### 1.1.3. Touch Sensor Types and Configurations

The touch sensor 140 may be an optical touch sensor or a projected capacitive touch sensor. In the case of an optical touch sensor, the touch sensor 140 may comprise PCB frames with mounted emitters and detectors. For a projected capacitive touch sensor, the touch sensor 140 may comprise a capacitive sensing layer made from materials such as indium tin oxide (ITO) layer, copper nanowire layer, graphene layer, silver nanowire layer, carbon nanotube layer, zinc oxide (ZnO) layer, conductive polymer layer, conductive mesh layer, or metal mesh layer.

### 1.2. Back Cover and Edge Covers

The main unit 100 may also comprise a back cover 150 and edge covers 160, which provide protection and a finished appearance to the touch display system 10.

### 1.2.1. Back Cover Materials and Functions

The back cover 150 may be made of materials such as aluminum, carbon fiber, stainless steel, or plastic. The back cover 150 provides protection for the touch sensor 140 and display 130, ensuring the durability and longevity of the touch display system 10. In some examples, support points 170 are attached to the back cover 150, which are used to connect the main unit 100 to the mounting component 200 for added rigidity.

### 1.2.2. Edge Cover Functions and Flexibility

The edge covers 160 may be attached to the edges 165 of the main unit 100, providing protection to the edges of the main unit 100 and a finished appearance. In some examples, the edge cover 160 may be flexible to conform to a curvature of the front surface 135 of the display 130. This flexibility allows the touch display system 10 to be adaptable to various user configurations and mounting options. For optical touch sensor configurations, the edge cover 160 may provide a light directing function for distributing light from the touch sensor 140 across the front surface 135 of the display 130, such as a surface of the transparent display cover 120.

### 2. Support Points and Connection to Mounting Component

In this section, we will discuss the support points and their connection to the mounting component in the touch display system. The support points are for providing a stable and secure connection between the main unit and the mounting component, ensuring the rigidity and proper functioning of the touch display system.

### 2.1. Positioning and Types of Support Points

In one example, the support points 170 are positioned on the rear surface 195 of the main unit 100. These support points may be located along the edges 165 of the main unit 100 or in the center of the rear surface of the main unit 100. The positioning of the support points 170 is for providing a secure connection between the main unit 100 and the mounting component 200, ensuring that the touch display system remains stable and rigid when connected.

The support points 170 may comprise various types of connection mechanisms, such as magnets, adhesive pads, clamps, clips, hooks, rivets, screws, snap-in connectors, suction cups, or Velcro strips. The choice of support point type depends on the specific requirements of the touch display system, such as the desired level of rigidity, ease of installation and removal, and compatibility with the mounting component 200.

### 2.2. Connection Methods and Adjustability

The connection between the support points 170 of the main unit 100 and the mounting component 200 provides rigidity and stability to the touch display system.

In some examples, the mounting component 200 comprises a first interface 180 for removably connecting to the support points 170 of the main unit 100. This removable connection allows for easy installation and removal of the main unit 100 from the mounting component 200, providing flexibility in the configuration and use of the touch display system.

The first interface 180 of the mounting component 200 may be adjustable to accommodate different curvatures of the front surface 135 of the display 130. This adjustability allows for the touch display system to be customized according to the specific requirements of the user, such as the desired curvature of the display 130 for optimal touch input detection.

In some examples, the connection between the support points 170 and the first interface 180 of the mounting component 200 may be further enhanced by using additional connection mechanisms, such as adjustable screws, spacers, wedges, or other suitable means. These additional connection mechanisms provide increased stability and rigidity to the touch display system, ensuring that the main unit 100 remains securely connected to the mounting component 200 during use.

The support points 170 and their connection to the mounting component 200 provide several advantages for the touch display system. By using lightweight layer components in the main unit 100 and a separate mounting component 200 for rigidity, the overall weight and cost of the touch screen can be reduced. Additionally, the adjustable connection between the support points 170 and the mounting component 200 allows for customization of the touch display system according to the specific requirements of the user, providing a versatile and adaptable solution for various touch display applications.

### 3. Mounting Component Design and Function

The mounting component 200 serves a role in the touch display system 10 by providing rigidity and support to the main unit 100 when connected. The mounting component 200 is configured to be easily connected and disconnected from the main unit 100, allowing for flexibility in the touch display system 10 configuration and usage. In this section, the function of the mounting component 200 and its various components will be discussed in detail.

### 3.1. First Interface for Connection to Main Unit

In one example, the mounting component 200 comprises a first interface 180 for removably connecting to the support points 170 of the main unit 100. The first interface 180 allows for a secure and stable connection between the main unit 100 and the mounting component 200, ensuring that the main unit 100 is adequately supported and rigid when connected. The first interface 180 may comprise magnets, magnet strips, adhesive pads, clamps, clips, hooks, rivets, screws, snap-in connectors, suction cups, or Velcro strips.

### 3.1.1. Adjustability for Curvature Control

In some examples, the first interface 180 of the mounting component 200 is adjustable to adjust a curvature of the front surface 135 of the display 130. This adjustability allows for the touch display system 10 to be optimized with respect to touch detection performance. For example, a slightly concave front surface 135 improves the touch detection performance. The adjustable first interface 180 may comprise mechanisms such as adjustable screws, spacers, or wedges to control the curvature of the front surface 135 of the display 130.

### 3.2. Body of Mounting Component

The body 190 of the mounting component 200 serves as the main structural component that connects the first interface 180 to the second interface 185. The body 190 may be made of materials such as aluminum, steel, plastic, or other rigid materials that provide adequate support and rigidity to the main unit 100 when connected. The body 190 may be designed to accommodate various sizes and shapes of main units 100, allowing for compatibility with a wide range of touch display systems.

### 3.3. Second Interface for Connection to Rigid Structure

In one example, the mounting component 200 comprises a second interface 185 for connecting to a rigid structure, such as a wall or floor stand. The second interface 185 provides a secure and stable connection between the mounting component 200 and the rigid structure, ensuring that the touch display system 10 remains rigid so that the display 130 or a front surface 135 maintains a defined shape. The second interface 185 may be designed to accommodate various types of rigid structures and connection methods, such as screws, bolts, brackets, or other fastening mechanisms.

### 3.3.1. Adjustability for Distance and Curvature Control

In some examples, the second interface 185 of the mounting component 200 is adjustable to adjust the distance between the main unit 100 and the rigid structure when connected to the rigid structure, such as a wall. This adjustability allows for adjusting a curvature of a front surface 135 of the display 130, since the aforementioned distance may be individually adjusted at each support point 170 across the main unit 100. Additionally, the touch display system 10 to be customized to different installation environments and requirements, providing a more versatile and adaptable touch display solution. The adjustable second interface 185 may comprise mechanisms such as adjustable screws, spacers, or wedges to control the distance between the main unit 100 and the rigid structure and thereby the curvature of the front surface 135 of the display 130.

The mounting component 200, with its adjustable first and second interfaces 180 and 185, provides a versatile and adaptable touch display system 10 that can be customized to different user preferences, installation environments, and requirements. This adaptability, combined with the lightweight and flexible design of the main unit 100, results in a touch display system 10 that is more cost-effective, user-friendly, and efficient than traditional touch display systems.

### 4. User Configurations and Flexibility

This section describes the user configurations and flexibility of the touch display system 10, which allows for different configurations depending on whether the main unit 100 is connected to the mounting component 200 or not. The touch display system 10 provides advantages such as adaptability to various user requirements and environments, as well as the ability to switch between configurations as needed.

### 4.1. First User Configuration: Disconnected From Mounting Component

In one example, the first user configuration of the touch display system 10 occurs when the main unit 100 is disconnected from the mounting component 200. In this configuration, the main unit 100 is flexible, allowing the front surface 135 of the display 130 to have a variable curvature.

### 4.1.1. Variable Curvature and Flexibility

In some examples, the variable curvature of the front surface 135 of the display 130 is achieved by the flexibility of the main unit 100 when disconnected from the mounting component 200. The main unit 100 may comprise lightweight layer components 110, such as the display 130, touch sensor 140, and optional transparent display cover 120, which contribute to the flexibility of the main unit 100. The edge covers 160 may also be flexible, allowing them to conform to the curvature of the front surface 135 of the display 130. This flexibility may be advantageous in situations where the touch display system 10 needs to be transported, stored, or used in environments where a rigid structure is not available or desired.

### 4.2. Second User Configuration: Connected to Mounting Component

In another example, the second user configuration of the touch display system 10 occurs when the main unit 100 is connected to the mounting component 200. In this configuration, the display 130 is rigidly fixed and the touch sensor 140 is configured to detect touch input on the display 130. A front surface 135 of the display 130 may have a pre-defined curvature. The mounting component 200 thus provides rigidity to the main unit 100 when connected.

### 4.2.1. Pre-defined Curvature and Rigidity

In some examples, the pre-defined curvature of the front surface 135 of the display 130 is achieved by connecting the main unit 100 to the mounting component 200. The mounting component 200 may comprise a first interface 180 for removably connecting to the support points 170 of the main unit 100, a body 190, and a second interface 185 for connecting to a rigid structure. The first interface 180 and/or the second interface 185 may be adjustable to adjust the curvature of the front surface 135 of the display 130, allowing for the touch display system 10 to be optimized with respect to touch detection performance. The mounting component 200 provides rigidity to the main unit 100 when connected, ensuring a stable and secure connection to the rigid structure and enhancing the overall user experience.

### 5. Method for Partitioning Touch Display

The method for partitioning a touch display into a main unit 100 and a mounting component 200 involves several steps and considerations to create a lightweight, flexible, and cost-effective touch display system. In one example, the method comprises the following steps and subsections:

### 5.1. Creation of Lightweight Stack of Layer Components

In one example, the method begins with providing a lightweight stack of layer components for the main unit 100, which may comprise a display 130, a transparent display cover 120, and a back cover 150. The selection of lightweight materials for these layer components contributes to the overall reduced weight and cost of the touch display system. The layer components may be selected based on their compatibility with the desired display type, touch sensor configuration, and desired flexibility of the main unit 100 when disconnected from the mounting component 200.

### 5.2. Bonding, Taping, or Screwing Layer Components

In some examples, the method involves bonding, taping, or screwing together the layer components into a sandwich structure. This step ensures that the layer components are securely attached to each other, providing a stable and durable main unit 100 while maintaining the desired flexibility when disconnected from the mounting component 200. The choice of bonding, taping, or screwing may depend on the materials used for the layer components, the desired level of rigidity, and the ease of assembly and disassembly for maintenance or repair purposes.

### 5.3. Connection of Mounting Component to Main Unit

In one example, the method comprises connecting a first interface 180 of the mounting component 200 to support points 170 of the main unit 100 arranged along edges 165 of the main unit 100. The mounting component 200 provides rigidity to the main unit 100 and a pre-defined curvature to a front surface 135 of the display 130, e.g. when connected to the main unit 100 and a rigid structure such as a wall or floor stand. The connection between the mounting component 200 and the main unit 100 may be removable, allowing for easy disconnection and reconfiguration of the touch display system.

### 5.4. Adjustability and Rigidity Control

In some examples, the method may comprise adjusting the distance between the main unit 100 and the rigid structure using an adjustable second interface 185 of the mounting component 200 when connected to a rigid structure. This adjustability allows for fine-tuning the curvature of the front surface 135 of the display 130 when connected to the mounting component 200. The first interface 180 and/or the second interface 185 may be adjustable to adjust the curvature of the front surface 135 of the display 130, providing additional control over the shape of the touch display system. The method for partitioning a touch display into a main unit 100 and a mounting component 200 offers several advantages, such as reduced weight and cost by using lightweight layer components and a separate mounting component for rigidity. This allows for the use of lightweight layer components in the main unit 100, reducing the overall weight and cost of the touch screen. Additionally, the method provides flexibility in the configuration of the touch display system, with the main unit 100 being flexible when disconnected from the mounting component 200 and rigid when connected, allowing for various user configurations and applications.

1-21. (canceled)

22. A touch display system comprising:
a main unit comprising a display and a touch sensor,
a mounting component,
wherein the main unit is flexible when not connected to the mounting component; and
wherein the mounting component is configured to provide rigidity to the main unit when connected to the main unit.

23. The touch display system according to claim 22, wherein a front surface of the display assumes a pre-defined curvature when the mounting component is connected to the main unit.

24. The touch display system according to claim 23, wherein the front surface assumes the pre-defined curvature when the mounting component is connected to the main unit and a rigid structure such as a wall or floor stand.

25. The touch display system according to claim 23, wherein the main unit further comprises an edge cover attached to edges of the main unit, wherein the edge cover is flexible to conform to a curvature of the front surface.

26. The touch display system according to claim 25, wherein the edge cover is configured to distribute light from the touch sensor across the front surface.

27. The touch display system according to claims 25, wherein the main unit further comprises a transparent display cover and a back cover, wherein the edge cover is connected to the back cover.

28. The touch display system according to claim 22, wherein the main unit further comprises support points positioned on a rear surface of the main unit for connecting the main unit to the mounting component.

29. The touch display system according to claim 28, wherein the mounting component comprises a first interface for removably connecting to the support points of the main unit, a body, and a second interface for connecting to the rigid structure.

30. The touch display system according to claim 29, wherein the second interface of the mounting component is adjustable to adjust a distance between the main unit and the rigid structure when connected to the rigid structure.

31. The touch display system according to claim 29, wherein the first interface and/or the second interface is adjustable to adjust a curvature of a front surface of the display.

32. The touch display system according to claim 29, wherein the first interface has a curved shape.

33. The touch display system according to claim 29, wherein the second interface comprises adjustable mounting points being individually adjustable to configure a uniformly shaped surface of the mounting component, and/or a symmetrically shaped surface of the mounting component, opposite a non-uniformly shaped wall, to which the main unit is connectable.

34. The touch display system according to claim 33, wherein the adjustable mounting points allow compensation of a wall shape selected from the group consisting of convex, concave, and S-shaped wall shapes.

35. The touch display system according to claim 33, wherein a first set of adjustable mounting points are arranged adjacent a center region of the mounting component and are configured to pull the mounting component towards a rigid surface such as a wall, and second set of adjustable mounting points are arranged outside the first set of adjustable mounting points, closer to a perimeter of the mounting component than the first set of adjustable mounting points, and are configured to push the mounting component from the rigid surface.

36. The touch display system according to claim 22, comprising a retention element for removably connecting the main unit to the mounting component.

37. The touch display system according to claim 26, wherein the retention element is arranged at the support points of the main unit and/or at the first interface of the mounting component.

38. The touch display system according to claim 22, wherein the first interface comprises a first support component configured to support the weight of the main unit when the mounting component is mounted to a rigid surface such as a wall.

39. The touch display system according to claim 22, wherein the display has a thickness of less than 5 mm.

40. The touch display system according to claim 22, wherein the touch display system has a first user configuration, when the main unit is disconnected from the mounting component, in which the main unit is flexing and a front surface of the display has a variable curvature, and a second user configuration, when the main unit is connected to the mounting component, in which the front surface of the display has a pre-defined curvature and the touch sensor is configured to detect touch input on the front surface.

41. A method for partitioning a touch display system into a main unit and a mounting component, the method comprising:
providing a lightweight stack of layer components for the main unit comprising a display, a transparent display cover and a back cover;
bonding, taping, or screwing together the layer components into a sandwich structure;
connecting a first interface of the mounting component to support points of the main unit, wherein the mounting component provides rigidity to the main unit and a pre-defined curvature to a front surface of the display when connected to the main unit.

42. The method according to claim 41, further comprising adjusting a distance between the main unit and a rigid structure such as a wall or floor stand using an adjustable second interface of the mounting component when connected to the rigid structure.
